(19) United States
(12) Patent Application Publication
(10) Pub. No.: US 2026/0095159 A1
(43) Pub. Date: Apr. 2, 2026

(54) FLIP-FLOP CIRCUIT WITH MULTIPLE DATA PATHS

(71) Applicant: APPLE INC., CUPERTINO, CA (US)

(72) Inventors: VIVEKANANDAN VENUGOPAL, SARATOGA, CA (US); QI YE, VISTA, CA (US); RAJIV MITTAL, SANTA CLARA, CA (US)

(21) Appl. No.: 18/988,832

(22) Filed: Dec. 19, 2024

Related U.S. Application Data
(60) Provisional application No. 63/700,579, filed on Sep. 27, 2024.

(51) Int. Cl. H03K 3/037

(52) U.S. Cl. CPC H03K 3/037

(57) ABSTRACT

A flip-flop circuit includes a first data path configured to provide a first path inverted value of an input signal to an output node of the flip-flop circuit based on a clock pulse. The flip-flop circuit also includes a second data path configured to provide a second path inverted value of the input signal to the output node via a master latch circuit and a slave latch circuit, based on a clock signal.

### CROSS REFERENCE TO RELATED APPLICATION

This application is a non-provisional utility application for patent entitled to a filing date and claiming the benefit of earlier-filed U.S. Provisional Patent Application No. 63/700,579, filed Sep. 27, 2024, which is hereby incorporated herein by reference in its entirety.

### BACKGROUND

### Technical Field

Embodiments described herein are related to the field of integrated circuit implementation, and more particularly to flip-flop circuits.

### Description of the Related Art

Integrated circuits (ICs), such as, for example, systems-on-chip (SoCs), may include a plurality of flip-flop circuits. As used herein, a “flip-flop circuit,” “flip-flop,” or simply “flop” refers to a circuit used to store a data bit value of an input signal. A flip-flop generally has two stable states, one of which is used to represent a logic one or logic high value and the other a logic zero or logic low value. A flip-flop may receive a clock signal to indicate when to read or sample the input signal and store the read value. Some types of flip-flops may be used to synchronize and control propagation of the input signal by limiting changes in the output of the flip-flop to occur in response to a rising or falling edge of the clock signal.

### SUMMARY OF VARIOUS EMBODIMENTS

Various embodiments of a flip-flop circuit are disclosed. In some implementations, the flip-flop circuit includes multiple data paths. In certain implementations, a first data path allows the flip-flop circuit to output data/signals more quickly (e.g., in a single stage/phase). In some implementations, a second data path includes a master latch circuit and a slave latch circuit. In certain implementations, the second data path also outputs the same data/signals, after the first data path has outputted the data/signals. If an errors/issues occur in the first data path, the data/signals may still be outputted via the second path, which allows the flip-flop circuit to continue to provide data/signals to other circuits/devices.

### BRIEF DESCRIPTION OF THE DRAWINGS

The following detailed description makes reference to the accompanying drawings, which are now briefly described.

FIG. 1 illustrates a diagram of an example integrated circuit, in accordance with one or more embodiments of the present disclosure.

FIG. 2 illustrates a diagram of a flip-flop, in accordance with one or more embodiments of the present disclosure.

FIG. 3 illustrates an example timing diagram, when an input signal transitions from low to high in accordance with one or more embodiments of the present disclosure.

FIG. 4 illustrates an example timing diagram when an input signal transitions from high to low, in accordance with one or more embodiments of the present disclosure.

FIG. 5 illustrates a flow diagram depicting an embodiment of a method for operating a flip-flop circuit, in accordance with one or more embodiments of the present disclosure.

FIG. 6 illustrates a block diagram of an example system, in accordance with one or more embodiments of the present disclosure.

While the disclosure is susceptible to various modifications and alternative forms, specific embodiments thereof are shown by way of example in the drawings and will herein be described in detail. It should be understood, however, that the drawings and detailed description thereto are not intended to limit the disclosure to the particular form illustrated, but on the contrary, the intention is to cover all modifications, equivalents and alternatives falling within the spirit and scope of the present disclosure as defined by the appended claims. The headings used herein are for organizational purposes only and are not meant to be used to limit the scope of the description. As used throughout this application, the word “may” is used in a permissive sense (i.e., meaning having the potential to), rather than the mandatory sense (i.e., meaning must). Similarly, the words “include,” “including,” and “includes” mean including, but not limited to.

### DETAILED DESCRIPTION OF EMBODIMENTS

In computing system, it may be desirable to store the logic state of various signals for periods of time. Latches or flip-flop circuits may be used to store the logic state of such signals. In some cases, flip-flop circuits are employed in logic paths to capture the logic states of groups of logic circuits and then forward those states onto other groups of logic circuits. In some cases, multiple flip-flops circuits may be grouped together to form a register file or other suitable storage array. Such register files may be employed to store larger amounts of data in a similar fashion to a memory.

Flip-flop circuits may use a state of a clock signal in order to determine when data is to be stored and/or outputted. For example, the flip-flop circuit may use a clock signal and/or a clock pulse to determine when a latch should store and/or output data/signals. It may take a longer period of time for a flip-flop to output data and/or signals. For example, it may take multiple stages/phases for a flip-flop to output data and/or signals. As such, it may be useful for a flip-flop to output data and/or signals more quickly. The embodiments illustrated in the drawings and described below may provide techniques for allowing a flip-flop to output data/signals more quickly via a faster data path, while still allowing the flip-flop to operate as a normal flip-flop if there are problem/issues in the faster data path.

Many terms commonly used in the design of ICs are referenced below in description of the illustrated embodiments. The present disclosure may refer to various terms described below.

A Metal-Oxide Semiconductor Field-Effect Transistor (MOSFET) describes a type of transistor that may be used in modern digital logic designs. MOSFETs are designed as one of two basic types, n-channel and p-channel. N-channel MOSFETs open a conductive path between the source and drain when a positive voltage greater than the transistor's threshold voltage is applied between the gate and the source. P-channel MOSFETs open a conductive path when a voltage greater than the transistor's threshold voltage is applied between the drain and the gate.

Complementary MOSFET (CMOS) describes a circuit designed with a mix of n-channel and p-channel MOSFETs. In CMOS designs, n-channel and p-channel MOSFETs may be arranged such that a high level on the gate of a MOSFET turns an n-channel transistor on, i.e., opens a conductive path, and turns a p-channel MOSFET off, i.e., closes a conductive path. Conversely, a low level on the gate of a MOSFET turns a p-channel on and an n-channel off. In addition, the term transconductance is used in parts of the disclosure. While CMOS logic is used in the examples, it is noted that any suitable digital logic process may be used for the circuits described in this disclosure.

It is noted that “high,” “high level,” and “logic high” refer to a voltage sufficiently large to turn on a n-channel MOSFET and turn off a p-channel MOSFET while “low,” “low level,” and “logic low” refer to a voltage that is sufficiently small enough to do the opposite. As used herein, a “logic signal” refers to a signal that transitions between a high logic level and a low logic level. In various other embodiments, different technology may result in different voltage levels for “low” and “high.”

The embodiments illustrated and described herein may employ CMOS circuits. In various other embodiments, however, other suitable technologies may be employed.

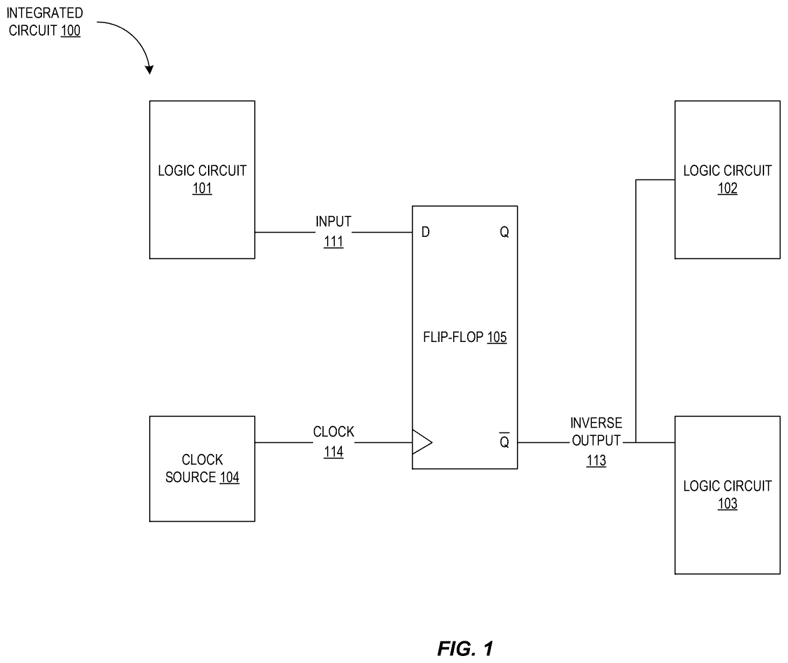

FIG. 1 illustrates a diagram of an example integrated circuit 100, in accordance with one or more embodiments of the present disclosure. In the illustrated embodiment, integrated circuit 100 includes three logic circuits, 101-103, clock source 104, and flip-flop 105. Logic circuit 101 is coupled to an input of flip-flop 105 via input signal 111. Flip-flop 105 outputs inverse output signal 113, and inverse output signal 113 is received by logic circuits 102 and 103. Flip-flop 105 also receives clock signal 114 from clock source 104.

Logic circuits 101-103 may correspond to any suitable circuits used in an integrated circuit. For example, logic circuits 101-103 may correspond to circuits in a processor, a memory controller, a serial interface, and other like circuits. Clock source 104 may correspond to any suitable clock generation circuit, such as, e.g., a phase-locked loop, a frequency-locked loop, a crystal oscillator, and the like. In the present embodiment, logic circuit 101 generates input signal 111 which is received by flip-flop 105. Flip-flop 105 stores a value of input signal 111 dependent upon clock signal 114 from clock source 104. It is noted that a clock distribution network (not shown) may be employed, in various embodiments, to distribute clock signal 114 to flip-flop 105, other flip-flop circuits, and other circuits employing clock signal 114.

In various embodiments, flip-flop 105 may capture a state of input signal 111 in response to a rising edge (i.e., when clock signal 114 transitions from a logic low to a logic high), a falling edge (i.e., when clock signal 114 transitions from a logic high to a logic low), or either edge of clock signal 114. As used herein, the edge of clock signal 114 that triggers capturing the state of input signal 111 is referred to the “active edge.”

Flip-flop 105 generates inverse output signal 113 with a value opposite to the captured state of input signal 111. The value of inverse output signal 113 remains unchanged despite changes in the state of input signal 111 until a next active clock edge is received.

In one embodiment, the flip-flop 105 may include multiple data paths. A first data path may allow the flip-flop 105 to output the inverse output signal 113 more quickly (e.g., in a single stage/phase). For example, the input signal 111 may be directly received, inverted, and then outputted as inverse output signal 113. A second data path may include a master latch circuit and a slave latch circuit. The second data path may also output the inverse output signal 113 at a time after the first data path outputs the inverse output signal 113. In some implementations, a flip-flop circuit includes a first data path configured to provide a first path inverted value of an input signal to an output node of the flip-flop circuit based on a clock pulse. The flip-flop circuit also includes a second data path configured to provide a second path inverted value of the input signal to the output node via a master latch circuit and a slave latch circuit, based on a clock signal. If an errors/issues occur in the first data path (e.g., the voltage of the clock pulse is not high enough for the flip-flop 105 to use the clock pulse), the inverse output signal 113 may still be outputted via the second path, which allows the flip-flop 105 to continue to provide the inverse output signal 113 to logic circuits 102 and 103.

It is noted that the integrated circuit 100 illustrated in FIG. 1 is merely an example. In other embodiments, different circuit blocks, different numbers of circuit blocks, and different configurations of circuit blocks may be possible dependent upon the specific application for which the integrated circuit 12400 is intended.

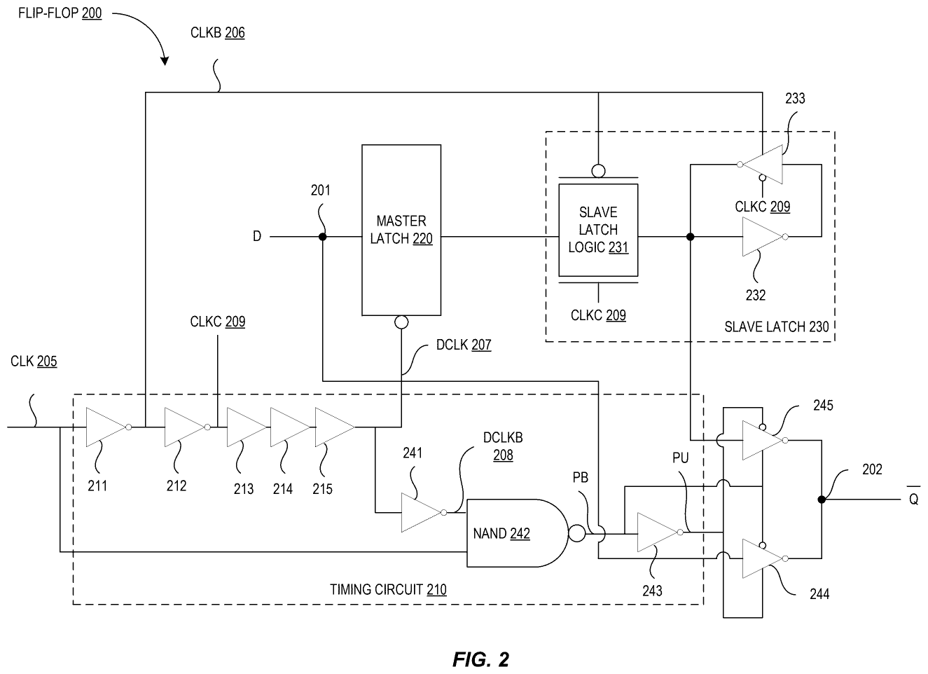

FIG. 2 illustrates diagram of an example flip-flop 200, in accordance with one or more embodiments of the present disclosure. Flip-flop 200 may be an example and/or implementation of flip-flop 105 illustrated in FIG. 1. Flip-flop 200 may also be referred to as a flip-flop circuit. Flip-flop 200 includes an input node 201, an output node 202, a master latch 220 and a slave latch 230. Slave latch 230 includes slave latch logic 231, a tri-state inverter 233, and an inverter 232. The slave latch logic 231 may include a one or more transmission gates (TXGs) or one or more stack gates (SXGs), as appropriate. For example, based on whether a transmission gate is used or a stack gate is used, the slave latch logic 231 may ensure that the polarity of signals is correct from D to Q̅. Flip-flop 200 also includes inverters 211 and 212, buffers 213 to 215, inverter 241, NAND 242 (e.g., a NAND gate or a NAND circuit), inverter 243, and tri-state inverters 244 and 245. Flip-flop 200 receives input signal D and clock signal 205. Flip-flop 200 generates an output signal Q̅. Q̅ may be the inverse of the input signal D. For example, if D has a value of logical 1 or high then Q̅ may have the value of logical 0 or low. In another example, if D has a value of logical 0 or low, then Q̅ may have the value logical 1 or high.

As illustrated in FIG. 2, the flip-flop 200 may include a timing circuit 210. The timing circuit 210 may receive, obtain, and/or generate a clock signal 205. For example, the clock signal 205 may be received from a circuit/device external to the flip-flop 200 (e.g., may be received from a clock circuit or some other appropriate device for generating the clock signal). In another example, the timing circuit 210 may include a clock circuit (or other appropriate device/circuit for generating the clock signal 205). Clock signal 205 may be referred to herein as CLK 205 (also referred to as a source clock signal when other flip-flop clock signals are derived therefrom).

In one embodiment, the timing circuit 210 may provide the clock signal 205 to other circuits, devices, components, etc., in the flip-flop 200. For example, the timing circuit 210 may provide the clock signal 209 (referred to herein as CLKC 209) to the tri-state inverter 233 and slave latch logic 231. As illustrated in FIG. 2, CLKC 209 is outputted by inverter 212. The timing circuit 210 may also invert the clock signal 205 to generate the inverted clock signal 206. The timing circuit 210 may further provide the inverted clock signal 206 to other circuits, devices, components, etc., in the flip-flop 200. For example, the timing circuit 210 may provide the inverted clock signal 206 to the slave latch 230. Inverted clock signal 206 may be referred to herein a CLKB 206.

In one embodiment, the timing circuit 210 generates a delayed clock signal 207 for the master latch 220 based on CLK 205. For example, inverter 212 may output CLK 205 to buffers 213, 214, and 215. In this example, the buffers 213, 214, and 215 delay the propagation, transmissions, etc., of CLK 205 to the master latch 220. The delayed clock signal 207 outputted by the buffers 213, 214, and 215 is provided to master latch 220. The delayed clock signal 207 may be referred to as DCLK 207.

In one embodiment, the timing circuit 210 generates a pulse PB and/or the pulse PU based on CLK 205. For example, CLK 205 may be provided to NAND 242. DCLK 207 may be outputted by buffer 215 and provided to inverter 241, which inverts DCLK 207 to generate an inverted delayed clock signal 208 (which may be referred to as DCLKB 208). The NAND 242 outputs/generates the pulse PB which is provided to the inverter 243, the tri-state inverter 244, and the tri-state inverter 245. The inverter 243 may invert the pulse PB to generate pulse PU.

In one embodiment, master latch 220 receives the state or value of input signal D while DCLK 207 is low. For example, the input signal D may have a value of logical 1 (e.g., high) or logical 0 (e.g., low). The input signal is received at node 201, which may be referred to as an input, an input node, etc. As referred to herein, DCLK 207, as well as other clock signals (e.g., CLK 205 and CLKB 206) disclosed herein, are referred to as “de-asserted” when in a low state and “asserted” when in a high state.

In one embodiment, when DCLK 207 transitions from the de-asserted state to the asserted state (e.g., from low to high), the value of input signal D (e.g., high/low, logical 0 or 1, etc.) is stored in the master latch 220 (e.g., latched in the master latch 220). The value of the input signal D is also provided to the slave latch 230. For example, master latch 220 may latch/store the value of the input signal D and may propagate the input signal D to the slave latch logic 231 of the slave latch 230. When CLK 205 is de-asserted, CLKB 206 is asserted. This causes the slave latch 230 to latch/store the value of the input signal D (which was received from master latch 220) and provide the input signal D to tri-state inverter 245 and inverter 232. Because master latch 220 receives DCLK 207 and slave latch 230 receives CLKB 206, both the master latch 220 and the slave latch 230 may be transparent for a period of time.

As illustrated in FIG. 2, when the input signal is provided to the master latch 220, the input signal D is also provided to tri-state inverter 244. The tri-state inverter 244 may invert the input signal D to generate the output signal Q̅, which is provided to output node 202, based on the pulses PB and PU. For example, when the pulse PU is asserted (e.g., goes to a high or a logical 1) and the pulse PB is de-asserted (e.g., goes to a low or logical 0), the tri-state inverter 244 may be enabled, operational, functioning, etc., and may invert the input signal D to generate the output signal Q̅ while tri-state inverter 245 is disabled. As shown, each tri-state inverter receives PU and PB to enable one tri-state inverter when the other is disabled forming a type of OR operation for outputting D on output node 202.

As discussed above, the input signal D may propagate, go through, etc., multiple different circuits or paths to reach output node 202. In one embodiment, a first set of circuits (e.g., a first path) for the input signal D to reach output node 202 may be via the tri-state inverter 244. As discussed above, the input signal D may be provided directly to the tri-state inverter 244 which may generate the output signal Q̅ based on pulses PU and PB. The first set of circuits (e.g., tri-state inverter 244) may be referred to as a first path, a data path, a primary path, a direct path, a fast path, a lower latency path, etc., for the input signal D. For example, the input signal D may be inverted and outputted as output signal Q̅ in one stage.

In one embodiment, a second set of circuits (e.g., a second path) for the input signal D to reach output node 202 may be via the master latch 220, the slave latch 230, and tri-state inverter 245. As discussed above, the input signal may be provided to the master latch 220, which may provide the input signal D to the slave latch 230, which may provide the input signal to tri-state inverter 245, which may invert the input signal D to generate output signal Q̅. The second set of circuits (e.g., the master latch 220, the slave latch 230, and tri-state inverter 245) may be referred to as a second path, a data path, a secondary path, an auxiliary path, a slow path, a higher latency path, a shadow path, etc., for the input signal D.

In one embodiment, the input signal D may propagate through the first set of circuits (e.g., tri-state inverter 244) and the second set of circuits (e.g., the master latch 220, the slave latch 230, and tri-state inverter 245) simultaneously (or at least partially simultaneously). For example, the input signal D may be propagating through one or more of the master latch 220 and/or the slave latch 230 while it is also propagating through the tri-state inverter 244.

In one embodiment, the first set of circuits (e.g., tri-state inverter 244) may generate the output signal Q̅ first, and may provide the output signal Q̅ to the output node 202. The second set of circuits (e.g., the master latch 220, the slave latch 230, and tri-state inverter 245) may also generate the output signal Q̅, but after the first set of circuits has already generated the output signal Q̅. For example, as shown, NAND 242 asserts PU (via PB) to first enable the first path tri-state buffer 244 when DCLKB and CLK 205 are asserted (logical highs) and de-assets PU to disable the first path tri-state buffer and enable the second path tris-state buffer 245 when DCLKB and CLK 205 are logical lows.

In one embodiment, the two sets of circuits for the input signal D (e.g., the first/fast path and the second/slow path) may allow the flip-flop 200 to generate the output signal Q̅ more quickly and/or reliably. For example, if only the master latch 220 and slave latch 230 are used to generate the output signal Q̅ (e.g., only the second path is used), it may take multiple stages for master latch 220 and the slave latch 230 to generate the output signal Q̅. In addition, if CLK 205 has a low voltage, this may cause a problem in the generation of the pulses PU and PB, which may then cause problems, issues, etc., when only the tri-state inverter 244 is used (e.g., when only the first path is used). Because the flip-flop 200 uses both sets of circuits (e.g., both paths) to receive and/or process the input signal D (to generate the output signal Q̅), the flip-flop 200 is able to generate the output signal Q̅ more quickly (via the first path) when CLK 205 has the appropriate voltage, but still correctly generate the output signal Q̅ (via the second path) when CLK 205 does not have the appropriate voltage.

It is noted that, to improve clarity and to aid in demonstrating the disclosed concepts, the block diagram illustrated in FIG. 2 has been simplified. In other embodiments, different and/or additional circuits, device, components, elements, etc., are possible and contemplated.

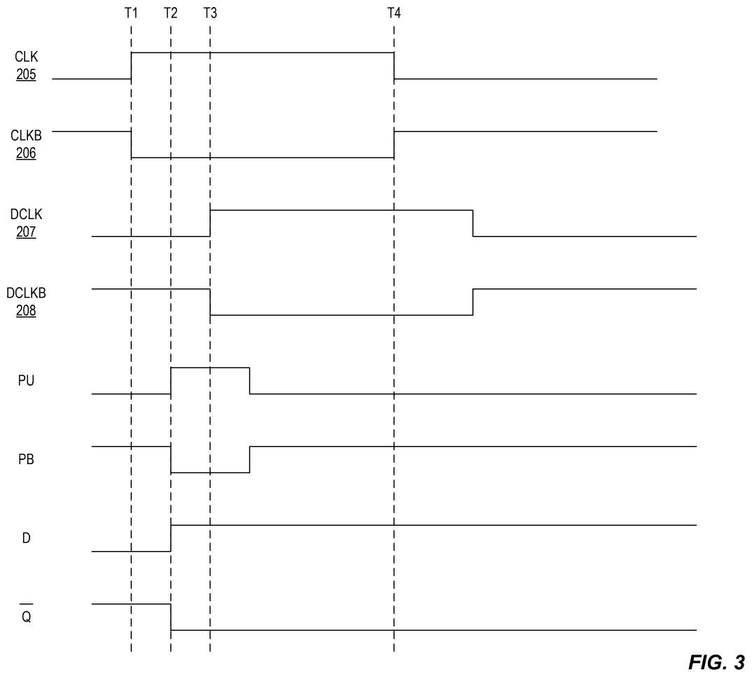

FIG. 3 illustrates an example timing diagram, in accordance with one or more embodiments of the present disclosure. The timing diagram illustrates the values of various signals used by the flip-flop 200 (illustrated in FIG. 2) at various points in time. For example, the timing diagram includes CLK 205, CLKB 206, DCLK 207, DCLKB 208, pulse PU, pulse PB, and input signal D, and output signal Q̅ (which are discussed above in FIG. 2). The timing diagram illustrates changes in the various signals (e.g., increase/decrease in the values/voltages of the signals) over time (e.g., time increase going from left to right).

At time T1, CLK 205 transitions from low to high (e.g., CLK 205 is asserted). Because CLKB 206 is the inverse of CLK 205, CLKB 206 transitions from high to low (e.g., CLKB 206 is de-asserted).

At time T2, pulse PU transitions from low to high. Because pulse PB is the inverse of pulse PU, pulse PB transitions from high to low. Also at time T2, the input signal D transitions from low to high (e.g., input signal D rises). The input signal D is inverted (e.g., by tri-state inverter 244 illustrated in FIG. 2) and output signal Q̅ transitions from high to low. The output signal Q̅ is outputted to the output node 202 of the flip-flop 200 at time T2.

At time T3, the DCLK 207 transitions from low to high. As discussed above, the DCLK 207 may be delayed in time when compared to CLK 205, by at least buffers 213-215. Because DCLKB 208 is the inverse of DCLK 207, DCLKB 208 transitions from high to low at time T3. The master latch 220 may store/latch the value of input signal D.

At time T4, CLK 205 transitions from high to low (e.g., CLK 205 is de-asserted). Because CLKB 206 is the inverse of CLK 205, CLKB 206 transitions from low to high (e.g., CLKB 206 is asserted). This may cause the slave latch 230 to provide input signal D to tri-state inverter 245 and tri-state inverter 245 may invert the input signal D to also generate output signal Q̅. The output signal Q̅ is outputted to the output node 202 of the flip-flop 200 at time T4.

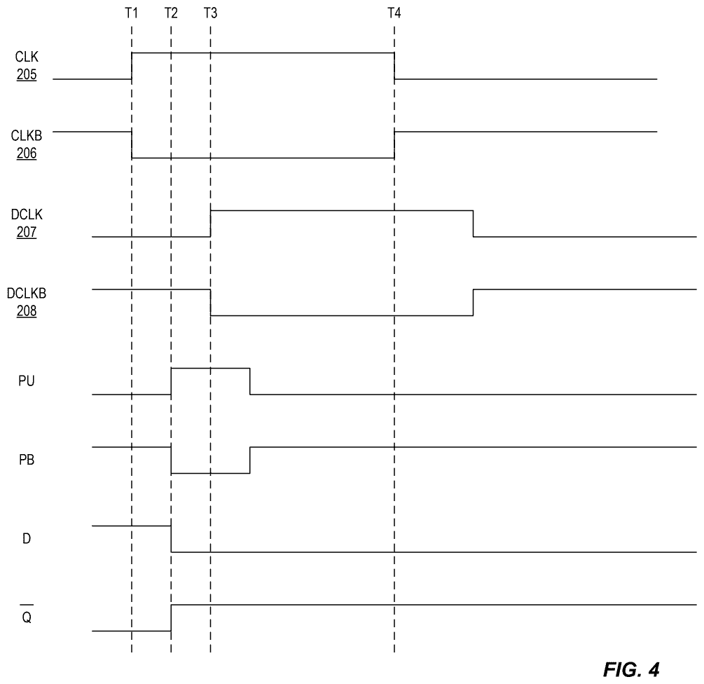

FIG. 4 illustrates another example timing diagram, in accordance with one or more embodiments of the present disclosure. The timing diagram of FIG. 4 illustrates the values of various signals used by the flip-flop 200 (illustrated in FIG. 2) at various points in time. For example, the timing diagram of FIG. 4 includes CLK 205, CLKB 206, DCLK 207, DCLKB 208, pulse PU, pulse PB, and input signal D, and output signal Q̅ (which are discussed above in FIG. 2). The timing diagram of FIG. 4 illustrates changes in the various signals (e.g., increase/decrease in the values/voltages of the signals) over time (e.g., time increase going from left to right).

At time T1, CLK 205 transitions from low to high (e.g., CLK 205 is asserted). Because CLKB 206 is the inverse of CLK 205, CLKB 206 transitions from high to low (e.g., CLKB 206 is de-asserted).

At time T2, pulse PU transitions from low to high. Because pulse PB is the inverse of pulse PU, pulse PB transitions from high to low. Also at time T2, the input signal D transitions from high to low (e.g., input signal D falls). The input signal D is inverted (e.g., by tri-state inverter 244 illustrated in FIG. 2) and output signal Q̅ transitions from low to high. The output signal Q̅ is outputted to the output node 202 of the flip-flop 200 at time T2.

At time T3, the DCLK 207 transitions from low to high. As discussed above, the DCLK 207 may be delayed in time when compared to CLK 205. Because DCLKB 208 is the inverse of DCLK 207, DCLKB 208 transitions from high to low at time T3. The master latch 220 may store/latch the value of input signal D.

At time T4, CLK 205 transitions from high to low (e.g., CLK 205 is de-asserted). Because CLKB 206 is the inverse of CLK 205, CLKB 206 transitions from low to high (e.g., CLKB 206 is asserted). This may cause the slave latch 230 to provide input signal D to tri-state inverter 245 and tri-state inverter 245 may invert the input signal D to also generate output signal Q̅. The output signal Q̅ is outputted to the output node 202 of the flip-flop 200 at time T4.

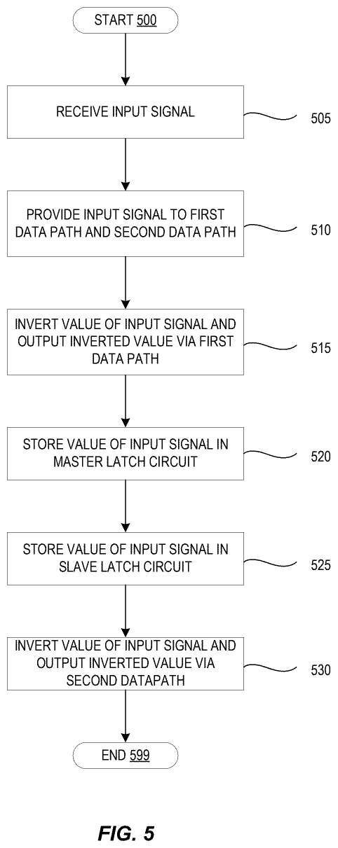

FIG. 5 illustrates a flow diagram depicting an embodiment of a method for operating a flip-flop circuit, in accordance with one or more embodiments of the present disclosure. The method, which may be applied to one or more of flip-flop 200 and flip-flop 105, as illustrated in FIGS. 1 to 2, starts at the block 500.

The method includes receiving an input signal at block 505. For example, the flip-flop may receive the input signal via an input node. At block 510, the method includes providing the input signal to a first data path and a second data path. As discussed above, the first data path may include a first tri-state inverter that is coupled to an output node of the flip-flop. In some implementations, the first data path includes the timing circuitry that generates the pulse PB and PU. The second data path may include a master latch circuit, a slave latch circuit, and a second tri-state inverter.

At block 515, the method includes inverting the value of the input signal, and outputting the inverted value via the first data path. For example, the first tri-state inverter may invert the value of the input signal based on a clock pulse, as discussed above. The first tri-state inverter may provide the first path inverted value to an output node of the flip-flop.

The method also includes storing the value of the input signal in the master latch circuit at block 520. For example, when a clock signal is asserted, the master latch circuit may store/latch the value of the input signal. At block 525, the value of the input signal is provided to the slave latch circuit and the slave latch circuit may latch/store the value of the input signal. For example, when the clock signal is de-asserted, the slave latch circuit may store/latch the value of the input signal. At block 530, the value of the input signal is inverted by the second tri-state inverter and outputted via the output node of the flip-flop and the method of FIG. 5 ends at block 599. The slave latch circuit may, for example, provide the value of the input signal to a second tri-state inverter which may provide the second path inverted value to the output node.

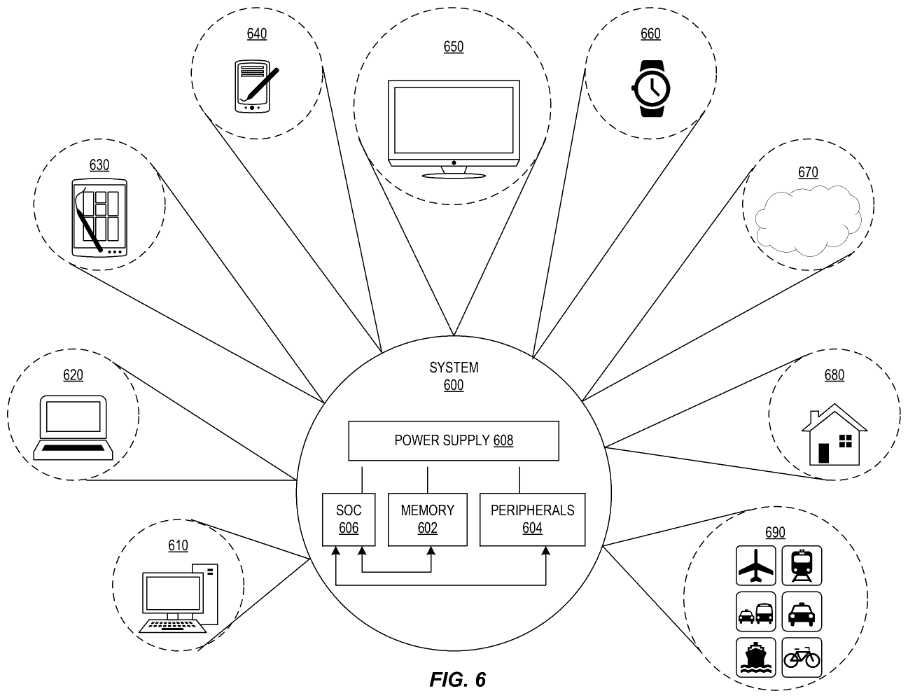

FIG. 6 illustrates a block diagram of an example system 600, in accordance with one or more embodiments of the present disclosure. The system 600 may incorporate and/or otherwise utilize the circuits, devices, components, methods, functions, and/or mechanisms described herein. In the illustrated embodiment, the system 600 includes at least one instance of a system on chip (SoC) 606 which may include multiple types of processing units, such as a central processing unit (CPU), a graphics processing unit (GPU), or otherwise, a communication fabric, and interfaces to memories and input/output devices. In some embodiments, one or more processors in SoC 606 includes multiple execution lanes and an instruction issue queue. In various embodiments, SoC 606 is coupled to external memory 602, peripherals 604, and power supply 608. The system 600 may use plates (with regions and/or vias) that are coupled to various components (e.g., coupled to SoC 606).

A power supply 608 is also provided which supplies the supply voltages to SoC 606 as well as one or more supply voltages to the memory 602 and/or the peripherals 604. In various embodiments, power supply 608 represents a battery (e.g., a rechargeable battery in a smart phone, laptop or tablet computer, or other devices). In some embodiments, more than one instance of SoC 606 is included (and more than one external memory 602 is included as well).

The memory 602 is any type of memory, such as dynamic random access memory (DRAM), synchronous DRAM (SDRAM), double data rate (DDR, DDR2, DDR3, etc.) SDRAM (including mobile versions of the SDRAMs such as mDDR3, etc., and/or low power versions of the SDRAMs such as LPDDR2, etc.), RAMBUS DRAM (RDRAM), static RAM (SRAM), etc. One or more memory devices are coupled onto a circuit board to form memory modules such as single inline memory modules (SIMMs), dual inline memory modules (DIMMs), etc. Alternatively, the devices are mounted with a SoC or an integrated circuit in a chip-on-chip configuration, a package-on-package configuration, or a multi-chip module configuration.

The peripherals 604 include any desired circuitry, depending on the type of system 600. For example, in one embodiment, peripherals 604 includes devices for various types of wireless communication, such as Wi-Fi, Bluetooth, cellular, global positioning system, etc. In some embodiments, the peripherals 604 also include additional storage, including RAM storage, solid state storage, or disk storage. The peripherals 604 include user interface devices such as a display screen, including touch display screens or multitouch display screens, keyboard or other input devices, microphones, speakers, etc.

As illustrated, system 600 is shown to have application in a wide range of areas. For example, system 600 may be utilized as part of the chips, circuitry, components, etc., of a desktop computer 610, laptop computer 620, tablet computer 630, cellular or mobile phone 640, or television 650 (or set-top box coupled to a television). Also illustrated is a smartwatch and health monitoring device 660. In some embodiments, smartwatch may include a variety of general-purpose computing related functions. For example, smartwatch may provide access to email, cellphone service, a user calendar, and so on. In various embodiments, a health monitoring device may be a dedicated medical device or otherwise include dedicated health related functionality. For example, a health monitoring device may monitor a user's vital signs, track proximity of a user to other users for the purpose of epidemiological social distancing, contact tracing, provide communication to an emergency service in the event of a health crisis, and so on. In various embodiments, the above-mentioned smartwatch may or may not include some or any health monitoring related functions. Other wearable devices are contemplated as well, such as devices worn around the neck, devices that are implantable in the human body, glasses designed to provide an augmented and/or virtual reality experience, and so on.

System 600 may further be used as part of a cloud-based service(s) 670. For example, the previously mentioned devices, and/or other devices, may access computing resources in the cloud (i.e., remotely located hardware and/or software resources). Still further, system 600 may be utilized in one or more devices of a home 680 other than those previously mentioned. For example, appliances within the home may monitor and detect conditions that warrant attention. For example, various devices within the home (e.g., a refrigerator, a cooling system, etc.) may monitor the status of the device and provide an alert to the homeowner (or, for example, a repair facility) should a particular event be detected. Alternatively, a thermostat may monitor the temperature in the home and may automate adjustments to a heating/cooling system based on a history of responses to various conditions by the homeowner. Also illustrated in FIG. 6 is the application of system 600 to various modes of transportation 690. For example, system 600 may be used in the control and/or entertainment systems of aircraft, trains, buses, cars for hire, private automobiles, waterborne vessels from private boats to cruise liners, scooters (for rent or owned), and so on. In various cases, system 600 may be used to provide automated guidance (e.g., self-driving vehicles), general systems control, and otherwise. These any many other embodiments are possible and are contemplated. It is noted that the devices and applications illustrated in FIG. 6 are illustrative only and are not intended to be limiting. Other devices are possible and are contemplated.

The present disclosure includes references to “an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent claims that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third” when applied to a feature do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation is used herein to refer to structure (i.e., something physical). More specifically, this formulation is used to indicate that this structure is arranged to perform the one or more tasks during operation. A structure can be said to be “configured to” perform some tasks even if the structure is not currently being operated. Thus, an entity described or recited as being “configured to” perform some tasks refers to something physical, such as a device, circuit, a system having a processor unit and a memory storing program instructions executable to implement the task, etc. This phrase is not used herein to refer to something intangible.

In some cases, various units/circuits/components may be described herein as performing a set of tasks or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

Various units, circuits, or other components may be described as “configured to” perform a task or tasks. In such contexts, “configured to” is a broad recitation of structure generally meaning “having circuitry that” performs the task or tasks during operation. As such, the unit/circuit/component can be configured to perform the task even when the unit/circuit/component is not currently on. In general, the circuitry that forms the structure corresponding to “configured to” may include hardware circuits. Similarly, various units/circuits/components may be described as performing a task or tasks, for convenience in the description. Such descriptions should be interpreted as including the phrase “configured to.” Reciting a unit/circuit/component that is configured to perform one or more tasks is expressly intended not to invoke 35 U.S.C. § 112, paragraph (f) interpretation for that unit/circuit/component. More generally, the recitation of any element is expressly intended not to invoke 35 U.S.C. § 112, paragraph (f) interpretation for that element unless the language “means for” or “step for” is specifically recited. Should Applicant wish to invoke Section 112 (f) during prosecution of a United States patent application based on this disclosure, it will recite claim elements using the “means for” language.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), functional unit, memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements may be defined by the functions or operations that they are configured to implement. The arrangement and such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used to transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits or portions thereof may also be custom-designed in a schematic editor and captured into the integrated circuit design along with synthesized circuitry. The integrated circuits may include transistors and other circuit elements (e.g. passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

Numerous variations and modifications will become apparent to those skilled in the art once the above disclosure is fully appreciated. It is intended that the following claims be interpreted to embrace all such variations and modifications.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. An apparatus, comprising:
a flip-flop circuit comprising:
a first data path configured to provide a first path inverted value of an input signal to an output node of the flip-flop circuit based on a clock pulse; and
a second data path configured to provide a second path inverted value of the input signal to the output node via a master latch circuit and a slave latch circuit, based on a clock signal.

2. The apparatus of claim 1 wherein the first data path is configured to provide the first path inverted value of the input signal to the output node before the second data path provides the second path inverted value of the input signal to the output node.

3. The apparatus of claim 1 wherein the first data path comprises a first inverter circuit configured to output the first path inverted value to the output node and wherein the second data path comprises a second inverter circuit configured to output the second path inverted value.

4. The apparatus of claim 1, wherein the master latch circuit is configured to store a value of an input signal in response to an assertion of the clock signal; the slave latch circuit is configured to store an output value of the master latch circuit in response to a de-assertion of the clock signal and provide the stored output value of the master latch circuit to a tri-state inverter circuit configured to output the second path inverted value to the output node.

5. The apparatus of claim 1, wherein the first path comprises a timing circuit configured to generate the clock pulse based on the clock signal.

6. The apparatus of claim 3, wherein the first inverter circuit comprises a first tri-state inverter that comprises a first input configured to receive the input signal from an input node and a first output configured to output the first path inverted value.

7. The apparatus of claim 5 wherein the timing circuit comprises an NAND circuit comprising a first input configured to receive a first clock signal and a second input configured to receive a second clock signal that is delayed from the first clock signal and an output that provides the clock pulse based on the first clock signal and the second clock signal.

8. The apparatus of claim 6, wherein the second inverter circuit comprises a second tri-state inverter comprising a first input coupled to an output of the slave latch circuit and a second output configured to output the second path inverted value.

9. The apparatus of claim 8, wherein the first tri-state inverter is operatively coupled to be enabled in response to the clock pulse and wherein the second tri-state inverter is operatively coupled to be disabled when the first tri-state inverter is enabled in response to the clock pulse.

10. A method, comprising:
receiving an input signal at an input node of a flip-flop circuit;
providing the input signal to a first data path of the flip-flop circuit, wherein the first data path provides a first path inverted value of the input signal to an output node of the flip-flop circuit based on a clock pulse; and
providing the input signal to a second data path of the flip-flop circuit, wherein the second data path provides a second path inverted value of the input signal to the output node via a master latch circuit and a slave latch circuit, based on a clock signal.

11. The method of claim 10 comprising:
providing the first path inverted value of the input signal to the output node before the second data path provides the second path inverted value of the input signal to the output node.

12. The method of claim 10, further comprising:
storing a value of the input signal in the master latch circuit, wherein the second path inverted value of the input signal is provided to the output node and wherein the value of the input signal is stored in the master latch circuit in response to an assertion of the clock signal.

13. The method of claim 12, further comprising:
storing the value of the input signal in the slave latch circuit in response to a de-assertion of the clock signal, wherein the slave latch circuit is further configured to output the value of the input signal in response to the de-assertion of the clock signal and wherein the value of the input signal is inverted to generate the second path inverted value.

14. The method of claim 10, wherein the first data path provides the first path inverted value of the input signal to the output node before the second data path provides the second path inverted value of the input signal.

15. An apparatus, comprising:
a clock generation circuit configured to generate a clock signal and a clock pulse;
a flip-flop circuit comprising:
a first data path comprising a first inverter circuit configured to provide a first path inverted value of an input signal to an output node of the flip-flop circuit based on the clock pulse; and
a second data path configured to provide a second path inverted value of the input signal to the output node via a master latch circuit, a slave latch circuit and a second inverter circuit, based on the clock signal and based on the clock pulse.

16. The apparatus of claim 15 wherein the first data path is configured to provide the first path inverted value of the input signal to the output node before the second data path provides the second path inverted value of the input signal to the output node.

17. The apparatus of claim 15, wherein the master latch circuit is configured to store a value of an input signal in response to an assertion of the clock signal; the slave latch circuit is configured to store an output value of the master latch circuit in response to a de-assertion of the clock signal and provide the stored output value of the master latch circuit to the second inverter circuit configured to output the second path inverted value to the output node.

18. The apparatus of claim 15, wherein the first inverter circuit comprises a first tri-state inverter that comprises a first input configured to receive the input signal from an input node and a first output configured to output the first path inverted value; and wherein the second inverter circuit comprises a second tri-state inverter comprising a first input coupled to an output of the slave latch circuit and a second output configured to output the second path inverted value.

19. The apparatus of claim 15 wherein the clock generation circuit comprises an NAND circuit comprising a first input configured to receive a first clock signal and a second input configured to receive a second clock signal that is delayed from the first clock signal and an output that provides the clock pulse based on the first clock signal and the second clock signal.

20. The apparatus of claim 18, wherein the first tri-state inverter is operatively coupled to be enabled in response to the clock pulse and wherein the second tri-state inverter is operatively coupled to be disabled when the first tri-state inverter is enabled in response to the clock pulse.
